(19) United States
(12) Patent Application Publication
(10) Pub. No.: US 2021/0082934 A1
(43) Pub. Date: Mar. 18, 2021

(54) SEMICONDUCTOR STORAGE DEVICE

(71) Applicant: KIOXIA CORPORATION, Tokyo (JP)

(72) Inventor: Toshiyuki IWAMOTO, Mie Mie (JP)

(73) Assignee: KIOXIA CORPORATION, Tokyo (JP)

(21) Appl. No.: 16/807,741

(22) Filed: Mar. 3, 2020

(30) Foreign Application Priority Data
Sep. 18, 2019 (JP) 2019-169870

(51) Int. Cl. H01L 27/11556; H01L 29/04; H01L 27/11582

(52) U.S. Cl. CPC H01L 27/11556; H01L 27/11582; H01L 29/045

(57) ABSTRACT

According to one embodiment, a semiconductor storage device includes: a single-crystal semiconductor substrate having a recessed surface; an under layer provided above the semiconductor substrate; a stacked body, provided over the under layer, that includes at least one conductive layer and at least one insulating layer alternately stacked on top of one another; a single-crystal semiconductor layer extending in a first direction perpendicular to the semiconductor substrate, penetrating the stacked body, and including a first end in contact with the recessed surface of the semiconductor substrate; and a memory film provided between the semiconductor layer and the at least one conductive layer. A crystal orientation of the semiconductor layer and a crystal orientation of the semiconductor substrate are the same.

### CROSS-REFERENCE TO RELATED APPLICATION(S)

This application is based upon and claims the benefit of priority from. Japanese Patent Application No. 2019-169870, filed Sep. 18, 2019, the entire contents of which are incorporated herein by reference.

### FIELD

Embodiments described herein relate generally to a semiconductor storage device.

### BACKGROUND

In a semiconductor storage device such as a three-dimensional semiconductor memory, it is known to use a semiconductor layer of polysilicon or the like for a channel formation region.

Examples of related art include JP-A-2012-146861.

### DESCRIPTION OF THE DRAWINGS

FIG. 1 is a schematic diagram showing a structure example of a semiconductor storage device.

FIG. 2 is a schematic diagram showing an example of a method for manufacturing the semiconductor storage device shown in FIG. 1.

FIG. 3 is a schematic diagram showing an example of the method for manufacturing the semiconductor storage device shown in FIG. 1.

FIG. 4 is a schematic diagram showing an example of the method for manufacturing the semiconductor storage device shown in FIG. 1.

FIG. 5 is a schematic diagram showing an example of the method for manufacturing the semiconductor storage device shown in FIG. 1.

FIG. 6 is a schematic diagram showing another structure example of the semiconductor storage device.

FIG. 7 is a schematic diagram showing an example of the method for manufacturing the semiconductor storage device.

FIG. 8 is a schematic diagram showing an example of the method for manufacturing the semiconductor storage device.

FIG. 9 is a schematic diagram showing another structure example of the semiconductor storage device.

FIG. 10 is a schematic diagram showing an example of a method for manufacturing the semiconductor storage device shown in FIG. 9.

FIG. 11 is a schematic diagram showing an example of the method for manufacturing the semiconductor storage device shown in FIG. 9.

FIG. 12 is a schematic diagram showing an example of the method for manufacturing the semiconductor storage device shown in FIG. 9.

FIG. 13 is a schematic diagram showing an example of the method for manufacturing the semiconductor storage device shown in FIG. 9.

FIG. 14 is a schematic diagram showing an example of the method for manufacturing the semiconductor storage device shown in FIG. 9.

FIG. 15 is a schematic diagram showing another structure example of the semiconductor storage device.

FIG. 16 is a schematic diagram showing another structure example of the semiconductor storage device.

FIG. 17 is a schematic diagram showing another structure example of the semiconductor storage device.

FIG. 18 is a schematic diagram showing another structure example of the semiconductor storage device.

FIG. 19 is a schematic diagram showing an example of a method for manufacturing the semiconductor storage device shown in FIG. 18.

FIG. 20 is a schematic diagram showing an example of the method for manufacturing the semiconductor storage device shown in FIG. 18.

FIG. 21 is a schematic diagram showing another structure example of the semiconductor storage device.

FIG. 22 is a schematic diagram showing an example of a method for manufacturing the semiconductor storage device shown in FIG. 21.

FIG. 23 is a schematic diagram showing an example of the method for manufacturing the semiconductor storage device shown in FIG. 21.

FIG. 24 is a schematic diagram showing an example of the method for manufacturing the semiconductor storage device shown in FIG. 21.

FIG. 25 is a schematic diagram showing another structure example of the semiconductor storage device.

### DETAILED DESCRIPTION

Embodiments provide a semiconductor storage device capable of increasing carrier mobility in a channel formation region.

In general, according to one embodiment, a semiconductor storage device includes: a single-crystal semiconductor substrate having a recessed surface; an under layer provided above the semiconductor substrate; a stacked body, provided over the under layer, that includes at least one conductive layer and at least one insulating layer alternately stacked on top of one another; a single-crystal semiconductor layer extending in a first direction perpendicular to the semiconductor substrate, penetrating the stacked body, and including a first end in contact with the recessed surface of the semiconductor substrate; and a memory film provided between the semiconductor layer and the at least one conductive layer. A crystal orientation of the semiconductor layer and a crystal orientation of the semiconductor substrate are the same.

Hereinafter, embodiments will be described with reference to the drawings. The relationship between the thickness and the planar dimension of each component described in the drawings, the ratio of the thickness of each component, and the like may differ from the actual product. In addition, in the embodiments, substantially the same components are denoted by the same reference numerals, and description thereof will be omitted as appropriate.

### First Embodiment

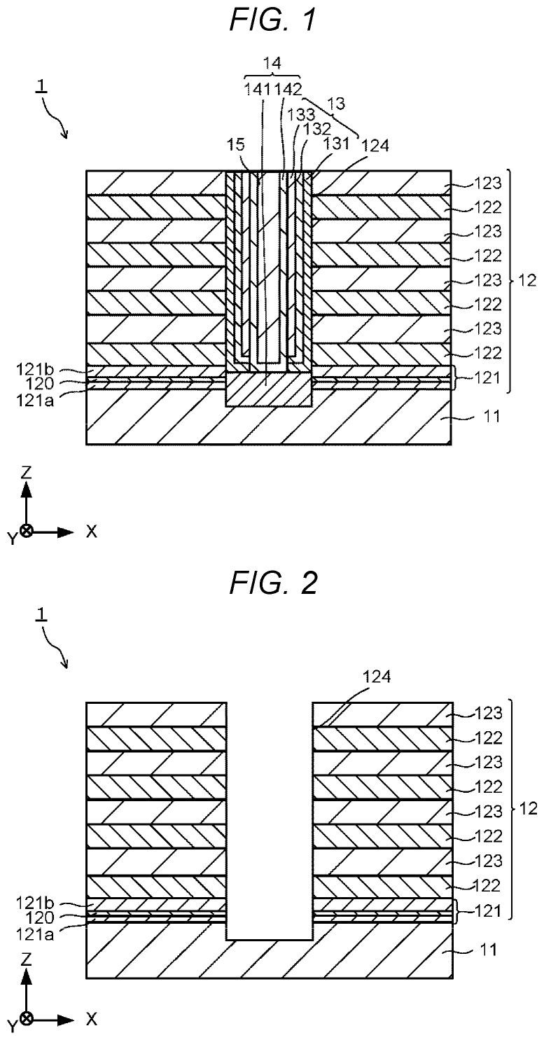

FIG. 1 is a schematic diagram showing a structure example of a semiconductor storage device, and shows a part of an X-Z cross section of a semiconductor storage device 1, the X-Z cross section including an X axis, a Y axis orthogonal to the X axis and a Z axis orthogonal to the X axis and the Y axis.

The semiconductor storage device 1 is an example of a three-dimensional semiconductor memory. The semiconductor storage device 1 includes a single-crystal semiconductor substrate 11, a stacked body 12, a memory film 13, a single-crystal semiconductor layer 14, and a core insulating film 15. The memory film 13, the single-crystal semiconductor layer 14, and the core insulating film 15 constitute a memory layer.

The single-crystal semiconductor substrate 11 contains, for example, silicon. The single-crystal semiconductor substrate 11 may contain other semiconductor materials without being limited to silicon.

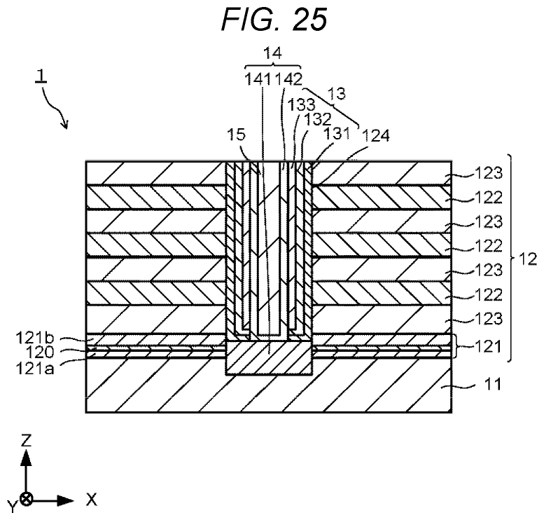

An under layer 121 of the stacked body 12 is provided above the single-crystal semiconductor substrate 11. The under layer 121 includes a first under layer 121a and a second under layer 121b. The first under layer 121a is provided above the single-crystal semiconductor substrate 11. The first under layer 121a is provided with a select gate line 120. The second under layer 121b is provided above the select gate line 120. Conductive layers 122 and insulating layers 123 are alternately stacked above the second under layer 121b. In some other embodiments, as shown in FIG. 25, the second under layer 121b may be in contact with the insulating layer 123. The first under layer 121a and the second under layer 121b include, for example, a silicon oxide film and a silicon nitride film. The conductive layer 122 constitutes a gate electrode (word line). The conductive layer 122 intersects with a Z-axis direction and extends in a direction parallel to a surface of the single-crystal semiconductor substrate 11 (Y-axis direction). The parallel direction may include a direction within ±10 degrees from the parallel direction (substantially parallel direction). The conductive layer 122 includes a doped silicon layer containing impurities (dopant) such as boron. The insulating layer 123 extends in the Y-axis direction. The insulating layer 123 includes, for example, a silicon oxide film. These films and layers are formed using a method such as chemical vapor deposition (CVD) or sputtering.

The memory film 13 is formed by sequentially stacking a block insulating film 131, a charge storage layer 132, and a tunnel insulating film 133 between the single-crystal semiconductor layer 14 and the conductive layer 122. The block insulating film 131 includes, for example, a silicon oxide film. The charge storage layer 132 includes, for example, a silicon nitride film. In addition, when forming a floating gate, the charge storage layer 132 contains, for example, polysilicon. A block insulating film (not shown) may be further provided between the charge storage layer 132 and the block insulating film 131. The further provided block insulating film is a high dielectric constant (High-k) material with a dielectric constant larger than that of the block insulating film 131, and contains, for example, hafnium silicate (HfSiO) or zirconium silicate (ZrSiO). The tunnel insulating film 133 includes a stacked film including, for example, a silicon oxide film and a silicon oxynitride film. These films and layers are formed, for example, using a method such as CVD.

The single-crystal semiconductor layer 14 constitutes a channel formation region, and has high carrier mobility since a crystal orientation thereof is the same as that of the single-crystal semiconductor substrate 11. If a difference in the crystal orientations is within ±20 degrees, it can be regarded as the same crystal orientation. The single-crystal semiconductor layer 14 includes a first single-crystal semiconductor layer 141 and a second single-crystal semiconductor layer 142. One end of the first single-crystal semiconductor layer 141 is located on a single-crystal semiconductor substrate 11 side next to the first under layer 121a and is in contact with a recessed surface of the single-crystal semiconductor substrate 11. The other end of the first single-crystal semiconductor layer 141 is located in the second under layer 121b. One end of the second single-crystal semiconductor layer 142 is in contact with the other end of the first single-crystal semiconductor layer 141. The memory film 13 is provided between the second single-crystal semiconductor layer 142 and the conductive layer 122 to form a memory cell. The second single-crystal semiconductor layer 142 extends in a direction perpendicular to the surface of the single-crystal semiconductor substrate (Z-axis direction).

The single-crystal semiconductor layer 14 contains, for example, silicon. The single-crystal semiconductor layer 14 preferably contains a semiconductor material same as that of the single-crystal semiconductor substrate 11, but may contain a different semiconductor material. The single-crystal semiconductor layer 14 preferably further contains hydrogen. Since hydrogen promotes single crystallization of the semiconductor layer, the single-crystal semiconductor layer 14 can be easily formed. A hydrogen concentration of the single-crystal semiconductor layer 14 is preferably higher than a hydrogen concentration of the single-crystal semiconductor substrate 11. The single-crystal semiconductor layer 14 contains impurities. An impurity concentration of the first single-crystal semiconductor layer 141 is higher than an impurity concentration of the second single-crystal semiconductor layer 142. An interface between the first single-crystal semiconductor layer 141 and the second single-crystal semiconductor layer 142 can be analyzed by different impurity concentrations. The impurity concentration of the second single-crystal semiconductor layer 142 is substantially uniform, but the impurity concentration in proximity of the interface with the first single-crystal semiconductor layer 141 is higher than the impurity concentration in proximity of the memory cell. The impurity is, for example, boron.

The core insulating film 15 fills, for example, an opening 124. In other words, the core insulating film 15 is provided in the second single-crystal semiconductor layer 142 extending in the Z-axis direction. The core insulating film 15 includes, for example, a silicon oxide film. The core insulating film 15 is formed, for example, using a method such as CVD.

FIGS. 2 to 5 are schematic diagrams showing an example of a method for manufacturing the semiconductor storage device shown in FIG. 1, and show a part of the X-Z cross section of the semiconductor storage device 1.

In the example of the method for manufacturing the semiconductor storage device shown in FIG. 1, first as shown in FIG. 2, the stacked body 12 is formed including the under layer 121 provided above the single-crystal semiconductor substrate 11, and the conductive layers 122 and insulating layers 123 alternately stacked above the under layer 121, and the opening 124 is formed to penetrate the under layer 121, the conductive layers 122, and the insulating layers 123 to expose the recessed surface of the single-crystal semiconductor substrate 11.

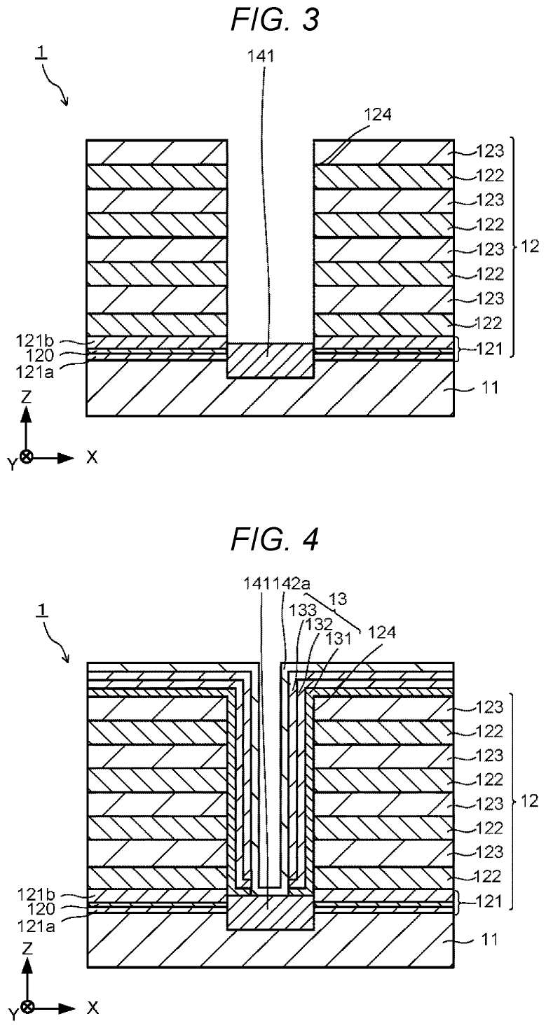

Next, as shown in FIG. 3, the first single-crystal semiconductor layer 141 is formed above the recessed surface of the single-crystal semiconductor substrate 11 in the opening 124. The first single-crystal semiconductor layer 141 is formed by forming an amorphous semiconductor layer above the single-crystal semiconductor substrate 11 and epitaxially growing the amorphous semiconductor layer.

Next, as shown in FIG. 4, the memory film 13 is formed by sequentially stacking the block insulating film 131, the charge storage layer 132, and the tunnel insulating film 133 on an inner wall surface of the opening 124 using a method such as CVD, an opening is formed to penetrate the memory film 13 to expose a part of the first single-crystal semiconductor layer 141, and then an amorphous semiconductor layer 142a is formed above the first single-crystal semiconductor layer 141. The amorphous semiconductor layer 142a is, for example, an undoped amorphous semiconductor layer, and contains, for example, materials applicable to the second single-crystal semiconductor layer 142. Preferably, the amorphous semiconductor layer 142a further contains hydrogen. Accordingly, the amorphous semiconductor layer 142a can be easily single-crystallized. The amorphous semiconductor layer 142a is formed, for example, using a method such as CVD.

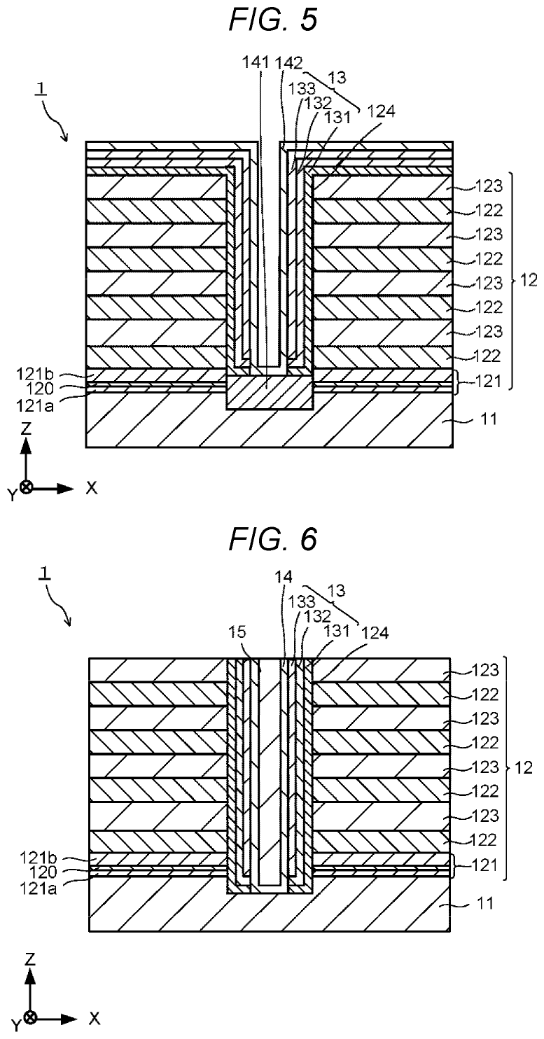

Next, the amorphous semiconductor layer 142a is annealed to crystallize the amorphous semiconductor layer 142a. Since the amorphous semiconductor layer 142a is in contact with the first single-crystal semiconductor layer 141, as shown in FIG. 5, the second single-crystal semiconductor layer 142 having a crystal orientation same as the crystal orientation of the single-crystal semiconductor substrate 11 and the crystal orientation of the first single-crystal semiconductor layer 141 is formed by annealing. The annealing is performed using, for example, an electric furnace. An annealing temperature is preferably a low temperature, and is, for example, 350° C. or higher and 600° C. or lower. An annealing time is not particularly limited, and is, for example, 2 hours or longer.

Thereafter, by a surface treatment such as chemical mechanical polishing (CMP), a part of the memory film 13 and a part of the second single-crystal semiconductor layer 142 are removed and the core insulating film 15 is formed. Through the above steps, the semiconductor storage device shown in FIG. 1 can be manufactured.

In this way, in the present embodiment, the channel formation region is constituted using the single-crystal semiconductor layer 14 having the crystal orientation same as the crystal orientation of the single-crystal semiconductor substrate 11. In a semiconductor storage device such as a bit cost scalable (BiCS) three-dimensional semiconductor memory, it is required to prevent a decrease in a cell current along with high integration. When constituting the channel formation region using a polycrystalline semiconductor of polysilicon or the like, respective crystal grains have different crystal orientations and crystal grain boundaries, which lowers the carrier mobility and therefore lowers the cell current. In response to this, the carrier mobility in the channel formation region can be increased by using the single-crystal semiconductor layer 14.

As a method for single-crystallizing the amorphous semiconductor layer, a method is known in which the amorphous semiconductor layer is crystallized by adding a metal catalyst such as nickel. However, in the method, the metal catalyst tends to remain in the semiconductor layer, and for example, the reliability of the tunnel insulating film may decrease. In response to this, in the present embodiment, when the amorphous semiconductor layer is formed above the single-crystal semiconductor substrate 11 and the amorphous semiconductor layer is annealed at a low temperature to form the single-crystal semiconductor layer 14, the single-crystal semiconductor layer 14 can be formed without adding a metal catalyst to the amorphous semiconductor layer. Therefore, a concentration of the metal catalyst in the single-crystal semiconductor layer 14 can be made, for example, equal to or lower than a concentration of the metal catalyst in the single-crystal semiconductor substrate 11, and the decrease in reliability of the tunnel insulating film 133 can be prevented.

### Second Embodiment

FIG. 6 is a schematic diagram showing another structure example of the semiconductor storage device, and shows a part of the X-Z cross section of the semiconductor storage device 1.

The semiconductor storage device 1 includes the single-crystal semiconductor substrate 11, the stacked body 12, the memory film 13, the single-crystal semiconductor layer 14, and the core insulating film 15. Since the single-crystal semiconductor substrate 11, the stacked body 12, the memory film 13, and the core insulating film 15 are the same as the single-crystal semiconductor substrate 11, the stacked body 12, the memory film 13, and the core insulating film 15 of the first embodiment, the description thereof is omitted.

The single-crystal semiconductor layer 14 constitutes a channel formation region, and has high carrier mobility since the crystal orientation thereof is the same as that of the single-crystal semiconductor substrate 11. One end of the single-crystal semiconductor layer 14 is located on the single-crystal semiconductor substrate 11 side than the under layer 121 and is in contact with the recessed surface of the single-crystal semiconductor substrate 11. The single-crystal semiconductor layer 14 penetrates the stacked body 12 and extends in the direction (Z-axis direction) perpendicular to the surface of the single-crystal semiconductor substrate 11. The memory film 13 is provided between the single-crystal semiconductor layer 14 and the conductive layer 122. The block insulating film 131 is in contact with the recessed surface of the single-crystal semiconductor substrate 11. A part of the block insulating film 131 in contact with the single-crystal semiconductor layer 14 is provided between a part of the charge storage layer 132 and the single-crystal semiconductor substrate 11. In addition, the block insulating film 131 is provided between the under layer 121a and the single-crystal semiconductor layer 14 that are provided above the single-crystal semiconductor substrate 11. The charge storage layer 132 is provided between the block insulating film 131 and the single-crystal semiconductor layer 14. The tunnel insulating film 133 is provided between the charge storage layer 132 and the single-crystal semiconductor layer 14. For the other description of the single-crystal semiconductor layer 14, the description of the single-crystal semiconductor layer 14 of the first embodiment can be used as appropriate.

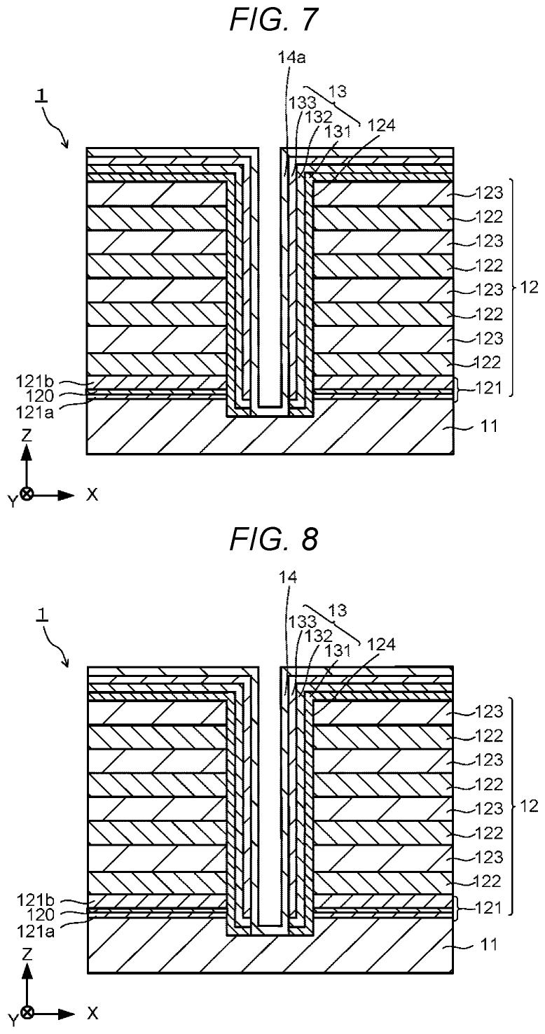

FIGS. 7 and 8 are schematic diagrams showing an example of the method for manufacturing the semiconductor storage device shown in FIG. 6, and show a part of the X-Z cross section of the semiconductor storage device 1.

In the example of the method for manufacturing the semiconductor storage device shown in FIG. 6, as similar to the first embodiment, the stacked body 12 and the memory film 13 are formed, the opening is formed to penetrate the memory film 13 to expose a part of the single-crystal semiconductor substrate 11, and then as shown in FIG. 7, an amorphous semiconductor layer 14a is formed above the single-crystal semiconductor substrate 11 and the memory film 13 in the opening 124.

The amorphous semiconductor layer 14a is an undoped amorphous semiconductor layer, and contains, for example, materials applicable to the single-crystal semiconductor layer 14. Preferably, the amorphous semiconductor layer 14a further contains hydrogen. Accordingly, the amorphous semiconductor layer 14a can be easily single-crystallized.

Next, the amorphous semiconductor layer 14a is annealed to crystallize the amorphous semiconductor layer 14a. Accordingly, as shown in FIG. 8, the single-crystal semiconductor layer 14 having the crystal orientation same as the crystal orientation of the single-crystal semiconductor substrate 11 can be formed. For annealing conditions, the conditions of the first embodiment can be used as appropriate.

Thereafter, by a surface treatment such as CMP, a part of the memory film 13 and a part of the single-crystal semiconductor layer 14 are removed and the core insulating film 15 is formed. Through the above steps, the semiconductor storage device 1 shown in FIG. 6 can be manufactured.

In this way, in the present embodiment, the channel formation region is constituted using the single-layer single-crystal semiconductor layer 14. Accordingly, the carrier mobility can be increased. In addition, in the present embodiment, since the single-crystal semiconductor layer 14 can be formed without adding the metal catalyst to the amorphous semiconductor layer 14a, for example, the decrease in reliability of the tunnel insulating film 133 can be prevented.

### Third Embodiment

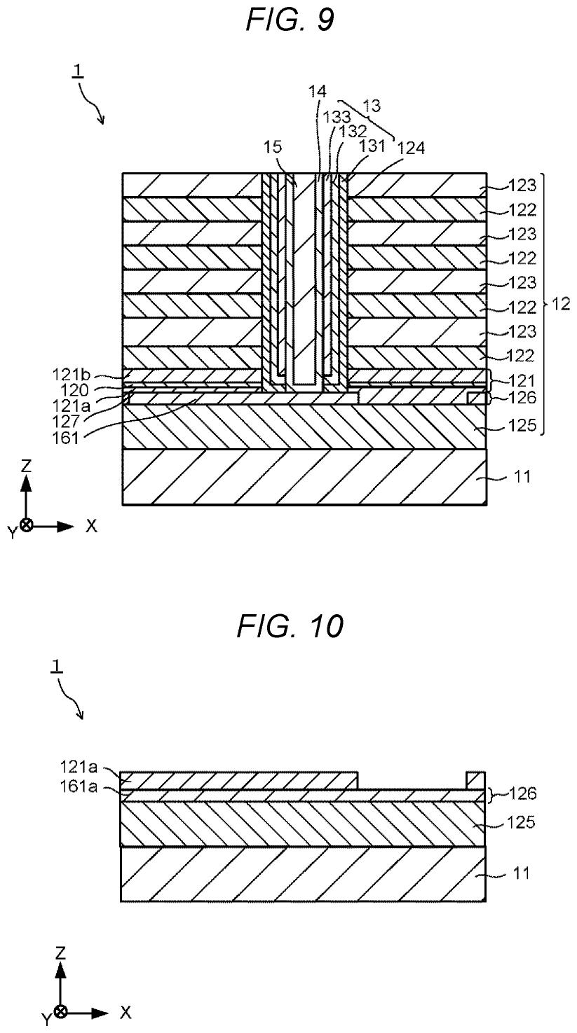

FIG. 9 is a schematic diagram showing another structure example of the semiconductor storage device, and shows a part of the X-Z cross section of the semiconductor storage device 1.

The semiconductor storage device 1 includes the single-crystal semiconductor substrate 11, the stacked body 12, the memory film 13, the single-crystal semiconductor layer 14, and the core insulating film 15. Since the single-crystal semiconductor substrate 11, the memory film 13, and the core insulating film 15 are the same as the single-crystal semiconductor substrate 11, the memory film 13, and the core insulating film 15 of the first embodiment, the description thereof is omitted.

The stacked body 12 includes the select gate line 120, the under layer 121, the conductive layers 122, the insulating layers 123, the opening 124, an interlayer insulating layer 125 provided above the single-crystal semiconductor substrate 11, a wiring layer 126 including a single-crystal layer 161 provided above the interlayer insulating layer 125, and a catalyst layer 127 provided above the interlayer insulating layer 125 and in contact with the single-crystal layer 161. The under layer 121 is provided above the interlayer insulating layer 125. The interlayer insulating layer 125 includes, for example, a silicon oxide film. The interlayer insulating layer 125 is formed, for example, using a method such as CVD. The select gate line 120 is provided between the first under layer 121a and the conductive layer 122 or the interlayer insulating layer 125 closest to the single-crystal semiconductor substrate 11. The wiring layer 126 intersects with the Z-axis direction and extends in the X-axis direction to, for example, constitute a source line. The wiring layer 126 is formed, for example, using a method such as CVD and sputtering. The single-crystal layer 161 contains, for example, silicon. The catalyst layer 127 contains a metal catalyst for forming the single-crystal layer 161. The metal catalyst contains, for example, nickel. The catalyst layer 127 is formed, for example, using a method such as sputtering. The wiring layer 126 and the catalyst layer 127 are in contact with the first under layer 121a. For the other description of the stacked body 12, the description of the stacked body 12 of the first embodiment can be used as appropriate.

The single-crystal semiconductor layer 14 constitutes a channel formation region, and has high carrier mobility since the crystal orientation is the same as that of the single-crystal layer 161. The single-crystal semiconductor layer 14 is provided above the single-crystal layer 161 and the memory film 13 in the opening 124. The single-crystal semiconductor layer 14 extends in the Z-axis direction and is in contact with the single-crystal layer 161. The single-crystal semiconductor layer 14 contains impurities. An impurity concentration of the single-crystal semiconductor layer 14 is higher than an impurity concentration of the wiring layer 126 (single-crystal layer 161). The interface between the single-crystal semiconductor layer 14 and the single-crystal layer 161 can be analyzed by different impurity concentrations. The impurity of the single-crystal semiconductor layer 14 is substantially uniform, but the impurity concentration in proximity of the single-crystal layer 161 is higher than the impurity concentration in proximity of a memory cell. The impurity is, for example, boron. For the other description of the single-crystal semiconductor layer 14, the description of the single-crystal semiconductor layer 14 of the first embodiment can be used as appropriate.

FIGS. 10 to 14 are schematic diagrams showing an example of the method for manufacturing the semiconductor storage device shown in FIG. 9, and show a part of the X-Z cross section of the semiconductor storage device 1.

In the example of the method for manufacturing the semiconductor storage device shown in FIG. 9, as shown in FIG. 10, the interlayer insulating layer 125, a non-single-crystal layer 161a, and the first under layer 121a are formed above the single-crystal semiconductor substrate 11, and the opening is formed to expose apart of the non-single-crystal layer 161a by processing the first under layer 121a. The interlayer insulating layer 125 includes, for example, a silicon oxide film. The non-single-crystal layer 161a is amorphous or polycrystalline and contains, for example, silicon.

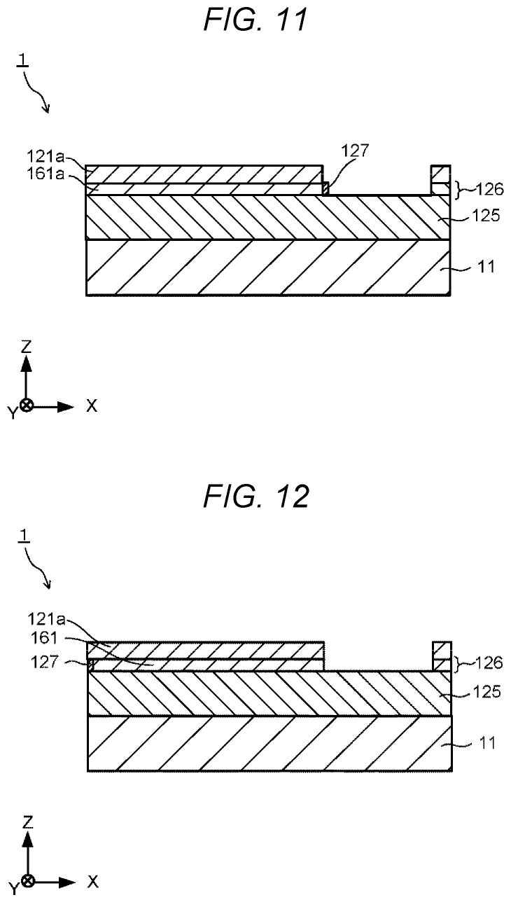

Next, as shown in FIG. 11, the non-single-crystal layer 161a is etched via the opening to form the catalyst layer 127 in contact with the non-single-crystal layer 161a.

Next, the non-single-crystal layer 161a is annealed while the metal catalyst of the catalyst layer 127 is diffused, so as to form the single crystal layer 161. Therefore, the wiring layer 126 including the single-crystal layer 161 is formed as shown in FIG. 12. A method for single-crystallizing the non-single-crystal layer 161a using the catalyst layer 127 is referred to as metal induced lateral crystallization (MILC). After the single-crystal layer 161 is formed, the opening may be filled with, for example, a layer of materials applicable to the first under layer 121a.

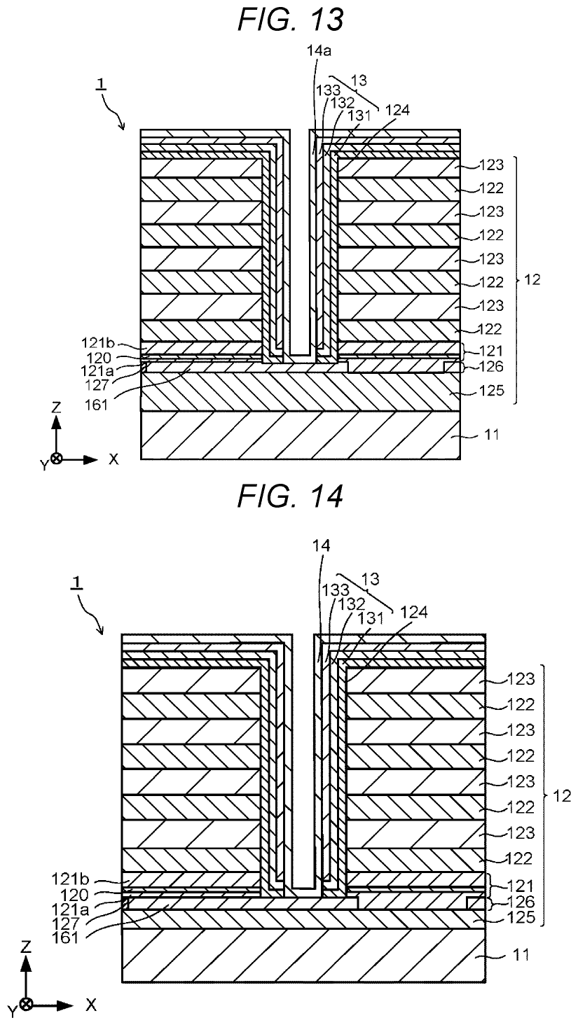

Next, as shown in FIG. 13, the select gate line 120, the second under layer 121b, and the conductive layers 122 and the insulating layers 123 alternately stacked above the second under layer 121b are sequentially stacked above the first under layer 121a, and the opening 124 is formed, so as to form the stacked body 12. Similar to the second embodiment, the memory film 13 and the amorphous semiconductor layer 14a are formed.

Next, the amorphous semiconductor layer 14a is annealed and crystallized. Accordingly, as shown in FIG. 14, the single-crystal semiconductor layer 14 having the crystal orientation same as the crystal orientation of the single-crystal layer 161 can be formed. For annealing conditions, the conditions of the first embodiment can be used as appropriate.

Thereafter, by a surface treatment such as CMP, a part of the memory film 13 and a part of the single-crystal semiconductor layer 14 are removed and the core insulating film 15 is formed. Through the above steps, the semiconductor storage device 1 shown in FIG. 9 can be manufactured.

In this way, in the present embodiment, the channel formation region is constituted using the single-crystal semiconductor layer 14 having the crystal orientation same as the crystal orientation of the single-crystal layer 161. Accordingly, the carrier mobility can be increased. In addition, in the present embodiment, since the single-crystal semiconductor layer 14 can be formed without adding the metal catalyst to the amorphous semiconductor layer 14a, for example, the decrease in reliability of the tunnel insulating film 133 can be prevented.

The present embodiment can be combined with other embodiments as appropriate. For example, the single-crystal semiconductor layer 14 may include the first single-crystal semiconductor layer 141 and the second single-crystal semiconductor layer 142 of the first embodiment.

### Fourth Embodiment

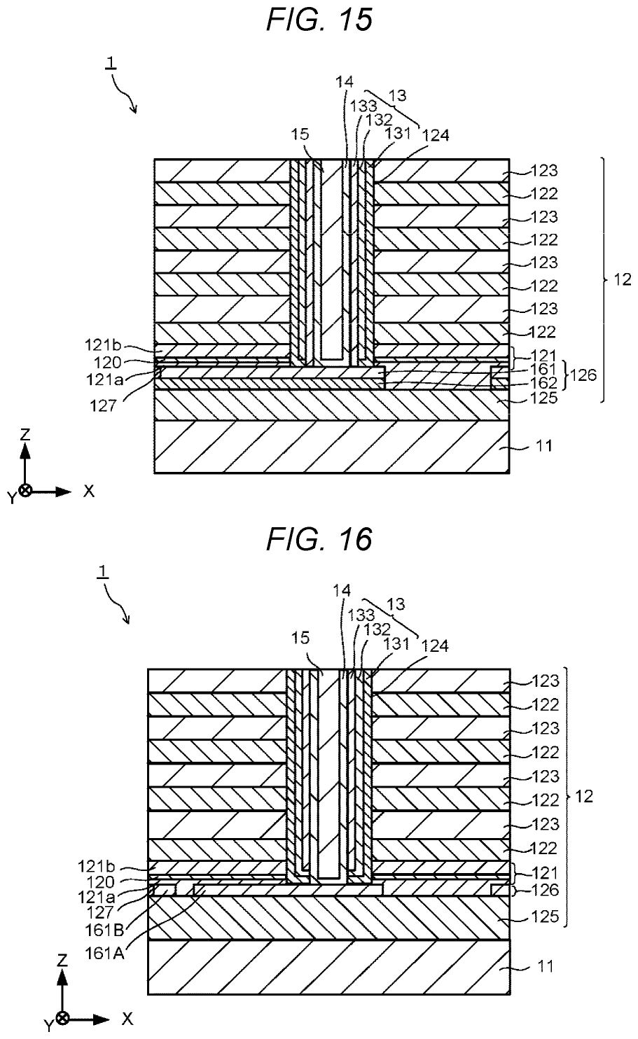

FIG. 15 is a schematic diagram showing another structure example of the semiconductor storage device, and shows a part of the X-Z cross section of the semiconductor storage device 1.

The semiconductor storage device 1 includes the single-crystal semiconductor substrate 11, the stacked body 12, the memory film 13, the single-crystal semiconductor layer 14, and the core insulating film 15. Since the description of the single-crystal semiconductor substrate 11, the memory film 13, and the core insulating film 15 is the same as the description of the first embodiment, the description thereof is omitted.

The stacked body 12 includes the select gate line 120, the under layer 121, the conductive layers 122, the insulating layers 123, the opening 124, the interlayer insulating layer 125 provided above the single-crystal semiconductor substrate 11, the wiring layer 126 including the single-crystal layer 161 and a metal layer 162 provided above the interlayer insulating layer 125, and the catalyst layer 127 provided above the interlayer insulating layer 125 and in contact with the single-crystal layer 161. The under layer 121 is provided above the interlayer insulating layer 125. The opening 124 penetrates the under layer 121, the conductive layers 122, and the insulating layers 123 in the Z-axis direction, so as to expose a part of the wiring layer 126 from the interlayer insulating layer 125. The interlayer insulating layer 125 includes, for example, a silicon oxide film. The interlayer insulating layer 125 is formed, for example, using a method such as CVD. The wiring layer 126 is in contact with the block insulating film 131. The wiring layer 126 constitutes, for example, a source line. The single-crystal layer 161 contains, for example, silicon. The single-crystal layer 161 is formed by a method same as that of the single-crystal layer 161 of the third embodiment. The catalyst layer 127 contains a metal catalyst for forming the single-crystal layer 161. The metal catalyst contains, for example, nickel. The metal layer 162 is in contact with the single-crystal layer 161. The metal layer 162 contains, for example, copper. The metal layer 162 preferably has an electrical resistance lower than that of the single-crystal layer 161. By forming the metal layer 162, an electrical resistance of the wiring layer 126 can be reduced. The catalyst layer 127 is formed, for example, using a method such as sputtering. The wiring layer 126 and the catalyst layer 127 are in contact with the first under layer 121a. For the other description of the stacked body 12, the description of the stacked body 12 of the first to third embodiments can be used as appropriate.

The single-crystal semiconductor layer 14 constitutes a channel formation region, and has high carrier mobility since the crystal orientation is the same as the crystal orientation of the single-crystal layer 161. The single-crystal semiconductor layer 14 is provided above the single-crystal layer 161 and the memory film 13 in the opening 124. The single-crystal semiconductor layer 14 extends in the Z-axis direction. The single-crystal semiconductor layer 14 is formed by a method same as that of the single-crystal semiconductor layer 14 of the third embodiment. For the other description of the single-crystal semiconductor layer 14, the description of the single-crystal semiconductor layer 14 of the first to third embodiments can be used as appropriate.

In this way, in the present embodiment, the channel formation region is constituted using the single-crystal semiconductor layer 14 having the crystal orientation same as the crystal orientation of the single-crystal layer 161. Accordingly, the carrier mobility can be increased. In the present embodiment, since the single-crystal semiconductor layer 14 can be formed without adding the metal catalyst to the amorphous semiconductor layer 14a, the decrease in reliability of the tunnel insulating film 133 can be prevented. Further, by using the metal layer 162 in the wiring layer 126, the electrical resistance of the wiring layer 126 can be reduced.

The present embodiment can be combined with other embodiments as appropriate. For example, the single-crystal semiconductor layer 14 may include the first single-crystal semiconductor layer 141 and the second single-crystal semiconductor layer 142 of the first embodiment.

### Fifth Embodiment

FIG. 16 is a schematic diagram showing another structure example of the semiconductor storage device, and shows a part of the X-Z cross section of the semiconductor storage device 1.

The semiconductor storage device 1 includes the single-crystal semiconductor substrate 11, the stacked body 12, the memory film 13, the single-crystal semiconductor layer 14, and the core insulating film 15. Since the description of the single-crystal semiconductor substrate 11, the memory film 13, and the core insulating film 15 is the same as the description of the first embodiment, the description thereof is omitted.

The stacked body 12 includes the select gate line 120, the under layer 121, the conductive layers 122, the insulating layers 123, the opening 124, the interlayer insulating layer 125 provided above the single-crystal semiconductor substrate 11, the wiring layer 126 including a single-crystal layer 161A and a single-crystal layer 161B provided above the interlayer insulating layer 125, and the catalyst layer 127 provided above the interlayer insulating layer 125 and in contact with the single-crystal layer 161. The under layer 121 is provided above the interlayer insulating layer 125. The interlayer insulating layer 125 includes, for example, a silicon oxide film. The interlayer insulating layer 125 is formed, for example, using a method such as CVD. The wiring layer 126 constitutes, for example, a source line. The single-crystal layer 161 contains, for example, silicon. The single-crystal layer 161A is spaced from the catalyst layer 127 and is in contact with the single-crystal semiconductor layer 14. The single-crystal layer 161B is spaced from the single-crystal layer 161A and is in contact with the catalyst layer 127. The single-crystal layer 161B is in a floating state. The catalyst layer 127 contains a metal catalyst for forming the single-crystal layer 161A and the single-crystal layer 161B. The metal catalyst contains, for example, nickel. The catalyst layer 127 is formed, for example, using a method such as sputtering. The wiring layer 126 and the catalyst layer 127 are in contact with the first under layer 121a. For the other description of the stacked body 12, the description of the stacked body 12 of the first embodiment can be used as appropriate.

The single-crystal layer 161A and the single-crystal layer 161B are formed, for example, by forming the single-crystal layer 161 of the third embodiment and then processing the single-crystal layer 161 to divide the single-crystal layer 161 into the single-crystal layer 161A and the single-crystal layer 161B.

In this way, in the present embodiment, a channel formation region is constituted using the single-crystal semiconductor layer 14 having the crystal orientation same as the crystal orientation of the single-crystal layer 161. Accordingly, the carrier mobility can be increased. In the present embodiment, since the single-crystal semiconductor layer 14 can be formed without adding the metal catalyst to the amorphous semiconductor layer 14a, the decrease in reliability of the tunnel insulating film 133 can be prevented.

Further, in the present embodiment, the metal catalyst can be prevented from diffusing into the single-crystal semiconductor layer 14 by separating the single-crystal layer 161B in contact with the catalyst layer 127 from the single-crystal layer 161A in contact with the single-crystal semiconductor layer 14. Therefore, for example, the decrease in reliability of the tunnel insulating film 133 can be prevented.

The present embodiment can be combined with other embodiments as appropriate. For example, the single-crystal semiconductor layer 14 may include the first single-crystal semiconductor layer 141 and the second single-crystal semiconductor layer 142 of the first embodiment.

### Sixth Embodiment

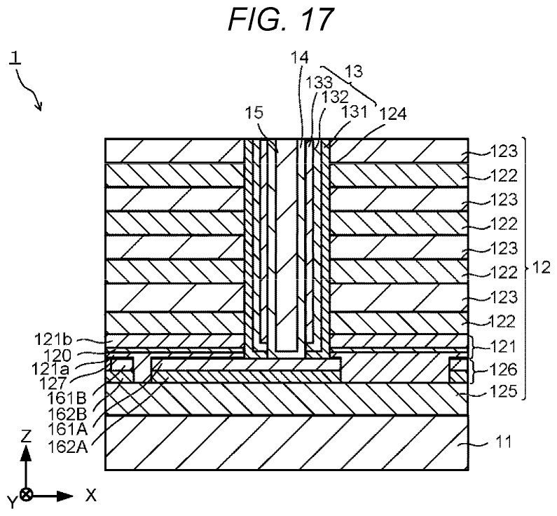

FIG. 17 is a schematic diagram showing another structure example of the semiconductor storage device, and shows a part of the X-Z cross section of the semiconductor storage device 1.

The semiconductor storage device 1 includes the single-crystal semiconductor substrate 11, the stacked body 12, the memory film 13, the single-crystal semiconductor layer 14, and the core insulating film 15. Since the description of the single-crystal semiconductor substrate 11, the memory film 13, and the core insulating film 15 is the same as the description of the first embodiment, the description thereof is omitted.

The stacked body 12 includes the select gate line 120, the under layer 121, the conductive layers 122, the insulating layers 123, the opening 124, the interlayer insulating layer 125 provided above the single-crystal semiconductor substrate 11, the wiring layer 126 including the single-crystal layer 161A, the single-crystal layer 161B, a metal layer 162A, and a metal layer 162B provided above the interlayer insulating layer 125, and the catalyst layer 127 provided above the interlayer insulating layer 125 and in contact with the single-crystal layer 161. The under layer 121 is provided above the interlayer insulating layer 125. The interlayer insulating layer 125 includes, for example, a silicon oxide film. The interlayer insulating layer 125 is formed, for example, using a method such as CVD. The wiring layer 126 constitutes, for example, a source line. The single-crystal layer 161A is spaced from the catalyst layer 127 and is in contact with the single-crystal semiconductor layer 14. The single-crystal layer 161B is spaced from the single-crystal layer 161A and is in contact with the catalyst layer 127. The metal layer 162A is spaced from the catalyst layer 127 and is in contact with the single-crystal layer 161A. The metal layer 162B is spaced from the metal layer 162A and is in contact with the single-crystal layer 161B. The single-crystal layer 161B and the metal layer 162B are in a floating state. The metal layer 162A and the metal layer 162B contain, for example, copper. The metal layer 162A and the metal layer 162B preferably have an electrical resistance lower than that of the single-crystal layer 161. By forming the metal layer 162A and the metal layer 162B, an electrical resistance of the wiring layer 126 can be reduced. The catalyst layer 127 contains a metal catalyst for forming the single-crystal layer 161A and the single-crystal layer 161B. The metal catalyst contains, for example, nickel. The catalyst layer 127 is formed, for example, using a method such as sputtering. The wiring layer 126 and the catalyst layer 127 are in contact with the first under layer 121a. For the other description of the stacked body 12, the description of the stacked body 12 of the first embodiment can be used as appropriate.

The single-crystal layer 161A, the single-crystal layer 161B, the metal layer 162A, and the metal layer 162B are formed, for example, by forming the single-crystal layer 161 and the metal layer 162 of the fourth embodiment and then processing the single-crystal layer 161 and the metal layer 162 to divide the single-crystal layer 161 and the metal layer 162 into the single-crystal layer 161A and the metal layer 162A, and the single-crystal layer 161B and the metal layer 162B.

In this way, in the present embodiment, a channel formation region is constituted using the single-crystal semiconductor layer 14 having the crystal orientation same as the crystal orientation of the single-crystal layer 161. Accordingly, the carrier mobility can be increased. In the present embodiment, since the single-crystal semiconductor layer 14 can be formed without adding the metal catalyst to the amorphous semiconductor layer 14a, the decrease in reliability of the tunnel insulating film 133 can be prevented.

Further, in the present embodiment, the metal catalyst can be prevented from diffusing into the single-crystal semiconductor layer 14 by separating the single-crystal layer 161B in contact with the catalyst layer 127 from the single-crystal layer 161A in contact with the single-crystal semiconductor layer 14. Therefore, the decrease in reliability of the tunnel insulating film 133 can be prevented.

The present embodiment can be combined with other embodiments as appropriate. For example, the single-crystal semiconductor layer 14 may include the first single-crystal semiconductor layer 141 and the second single-crystal semiconductor layer 142 of the first embodiment.

### Seventh Embodiment

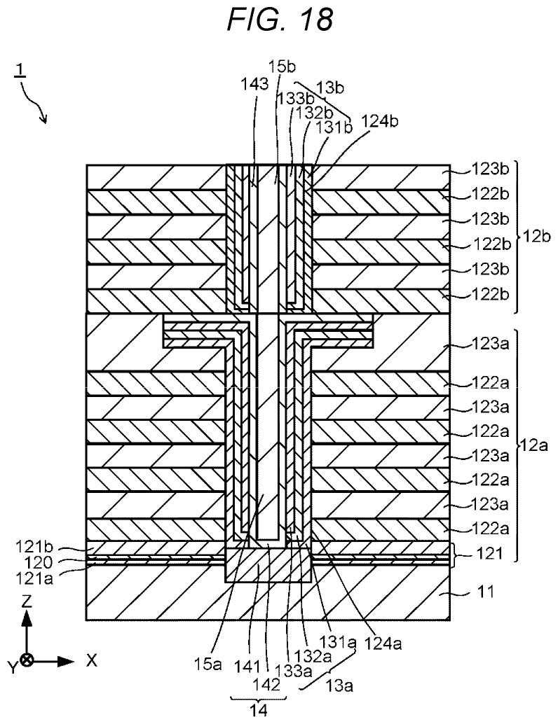

FIG. 18 is a schematic diagram showing another structure example of the semiconductor storage device, and shows a part of the X-Z cross section of the semiconductor storage device 1.

The semiconductor storage device 1 includes the single-crystal semiconductor substrate 11, a stacked body 12a, a stacked body 12b, a memory film 13a, a memory film 13b, a single-crystal semiconductor layer 14 including the first single-crystal semiconductor layer 141, the second single-crystal semiconductor layer 142, and a third single-crystal semiconductor layer 143, a core insulating film 15a, and a core insulating film 15b. Since the single-crystal semiconductor substrate 11, the stacked body 12a, the under layer 121, conductive layers 122a, insulating layers 123a, an opening 124a, the memory film 13a, a block insulating film 131a, a charge storage layer 132a, a tunnel insulating film 133a, and the core insulating film 15a are the same as the single-crystal semiconductor substrate 11, the stacked body 12, the under layer 121, the conductive layer 122, the insulating layer 123, the opening 124, the memory film 13, the block insulating film 131, the charge storage layer 132, the tunnel insulating film 133, and the core insulating film 15 of the first embodiment respectively, the description thereof is omitted.

The stacked body 12b includes the conductive layers 122b and the insulating layers 123b alternately stacked above the stacked body 12a. The conductive layer 122b constitutes, for example, a gate electrode (word line). The conductive layer 122b includes, for example, a doped silicon layer containing a dopant such as boron. The insulating layer 123b includes, for example, a silicon oxide film. An opening 124b penetrates the conductive layers 122b and the insulating layers 123b in the Z-axis direction. For the other description of the conductive layers 122b, the insulating layers 123b, and the opening 124b, the description of the conductive layer 122, the insulating layer 123, and the opening 124 of the first embodiment can be used as appropriate.

The memory film 13b is formed by sequentially stacking a block insulating film 131b, a charge storage layer 132b, and a tunnel insulating film 133b between the third single-crystal semiconductor layer 143 and the conductive layers 122b. For the other description of the block insulating film 131b, the charge storage layer 132b, and the tunnel insulating film 133b, the description of the block insulating film 131, the charge storage layer 132, and the tunnel insulating film 133 of the first to sixth embodiments can be used as appropriate.

One end of the third single-crystal semiconductor layer 143 is in contact with the other end of the second single-crystal semiconductor layer 142. The memory film 13b is provided between the third single-crystal semiconductor layer 143 and the conductive layer 122b to form a memory cell. The third single-crystal semiconductor layer 143 extends in the Z-axis direction. For the other description of the third single-crystal semiconductor layer 143, the description of the single-crystal semiconductor layer 14 of the first to sixth embodiments can be used as appropriate.

The core insulating film 15b fills, for example, the opening 124b in communication with the opening 124a. In other words, the core insulating film 15 is provided between the third single-crystal semiconductor layer 143 extending in the Z direction. The core insulating film 15b includes, for example, a silicon oxide film. The core insulating film 15b is formed, for example, using a method such as CVD.

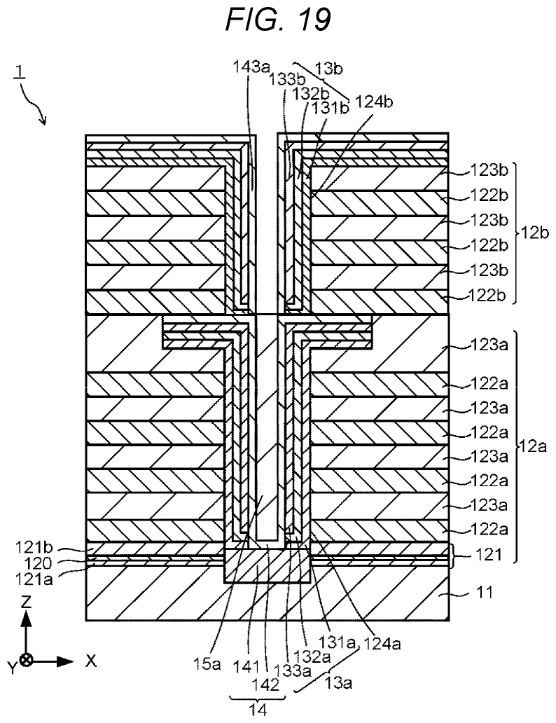

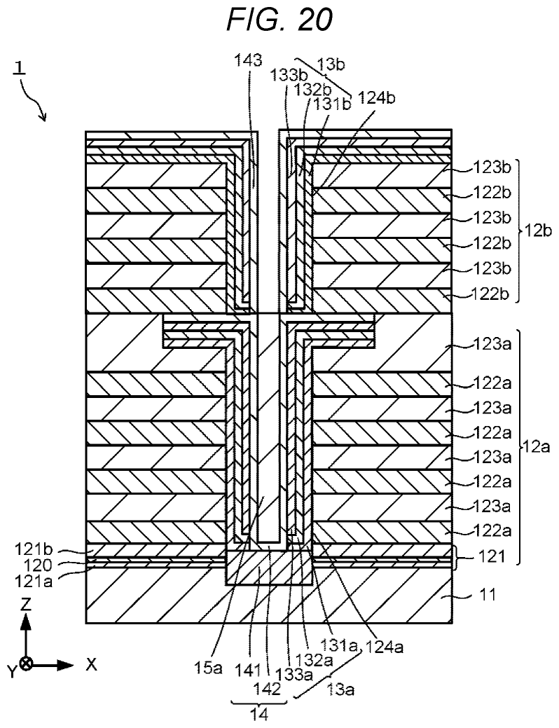

FIGS. 19 and 20 are schematic diagrams showing an example of the method for manufacturing the semiconductor storage device shown in FIG. 18, and show a part of the X-Z cross section of the semiconductor storage device 1.

In the example of the method for manufacturing the semiconductor storage device shown in FIG. 18, first as shown in FIG. 19, the stacked body 12a, the memory film 13a, the first single-crystal semiconductor layer 141, the second single-crystal semiconductor layer 142, and the core insulating film 15a are formed above the single-crystal semiconductor substrate 11 using a method similar to that of the first embodiment.

Next, as shown in FIG. 19, the stacked body 12b including the conductive layers 122b and insulating layers 123b alternately stacked above the stacked body 12a is formed, and the opening 124b is formed to penetrate the conductive layers 122b and the insulating layers 123b to expose a part of the second single-crystal semiconductor layer 142.

Next, as shown in FIG. 19, the memory film 13b is formed by sequentially stacking the block insulating film 131b, the charge storage layer 132b, and the tunnel insulating film 133b above an inner wall surface of the opening 124b.

Next, the opening is formed to penetrate the memory film 13b to expose a part of the second single-crystal semiconductor layer 142, and then an amorphous semiconductor layer 143a is formed above the second single-crystal semiconductor layer 142 in the opening 124b as shown in FIG. 19.

The amorphous semiconductor layer 143a is an undoped amorphous semiconductor layer, and contains, for example, materials applicable to the second single-crystal semiconductor layer 142. Preferably, the amorphous semiconductor layer 143a further contains hydrogen. Accordingly, the amorphous semiconductor layer 143a can be easily single-crystallized. The amorphous semiconductor layer 143a is formed, for example, using a method such as CVD.

Next, the amorphous semiconductor layer 143a is annealed to crystallize the amorphous semiconductor layer 143a. Accordingly, as shown in FIG. 20, the third single-crystal semiconductor layer 143 having the crystal orientation same as the crystal orientation of the single-crystal semiconductor substrate 11 and the crystal orientation of the second single-crystal semiconductor layer 142 can be formed. The annealing is performed using, for example, an electric furnace. For annealing conditions, the conditions of the first embodiment can be used as appropriate.

Thereafter, by a surface treatment such as CMP, a part of the memory film 13b and a part of the third single-crystal semiconductor layer 143 are removed and the core insulating film 15b is formed. Through the above steps, the semiconductor storage device 1 shown in FIG. 18 can be manufactured.

In this way, in the present embodiment, a channel formation region is constituted using the single-crystal semiconductor layer 14 having the crystal orientation same as the crystal orientation of the single-crystal semiconductor substrate 11. Accordingly, the carrier mobility of the channel formation region can be increased. In addition, in the present embodiment, since the single-crystal semiconductor layer 14 can be formed without adding a metal catalyst to the amorphous semiconductor layer 142a and the amorphous semiconductor layer 143a, for example, the decrease in reliability of the tunnel insulating film 133 can be prevented.

When the opening 124a and the opening 124b are too deep and the amorphous semiconductor layer 142a is single-crystallized, the single-crystal semiconductor layer 14 may be divided by migration. In order to deal with this, the single-crystal semiconductor layer 14 is formed in a plurality of steps, so that the single-crystal semiconductor layer 14 is prevented from being divided.

The present embodiment may be combined with other embodiments as appropriate. For example, similar to the second embodiment, the single-crystal semiconductor layer 14 may be constituted without forming the first single-crystal semiconductor layer 141.

### Eighth Embodiment

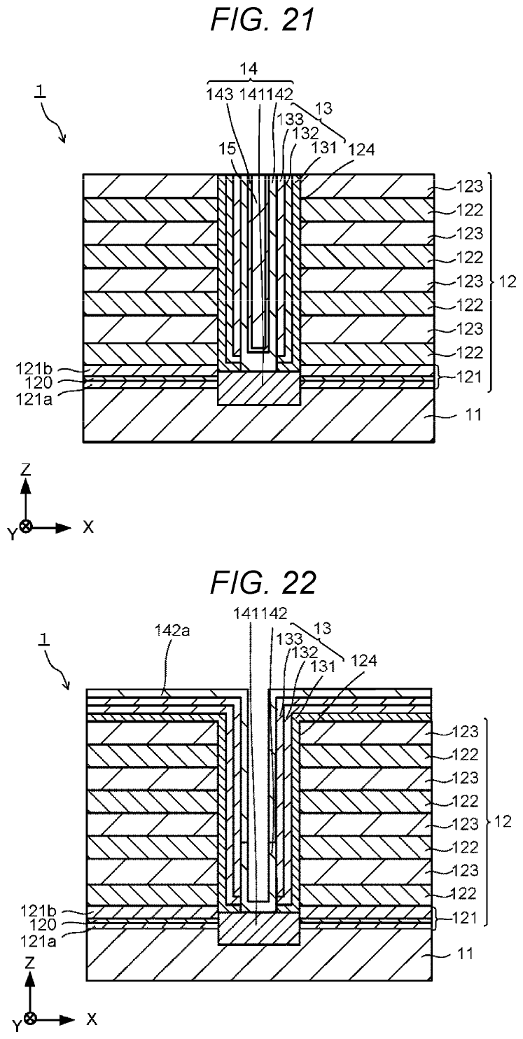

FIG. 21 is a schematic diagram showing another structure example of the semiconductor storage device, and shows a part of the X-Z cross section of the semiconductor storage device 1.

The semiconductor storage device 1 includes the single-crystal semiconductor substrate 11, the stacked body 12, the memory film 13, the single-crystal semiconductor layer 14 including the first single-crystal semiconductor layer 141, the second single-crystal semiconductor layer 142, and the third single-crystal semiconductor layer 143, and the core insulating film 15. Since the single-crystal semiconductor substrate 11, the stacked body 12, the under layer 121, the conductive layers 122, the insulating layers 123, the opening 124, the memory film 13, the block insulating film 131, the charge storage layer 132, the tunnel insulating film 133, the first single-crystal semiconductor layer 141, the second single-crystal semiconductor layer 142, and the core insulating film 15 are the same as the single-crystal semiconductor substrate 11, the stacked body 12, the under layer 121, the conductive layers 122, the insulating layers 123, the opening 124, the memory film 13, the block insulating film 131, the charge storage layer 132, the tunnel insulating film 133, the first single-crystal semiconductor layer 141, the second single-crystal semiconductor layer 142, and the core insulating film 15 of the first to seventh embodiments respectively, the description thereof is omitted.

The third single-crystal semiconductor layer 143 is provided above the second single-crystal semiconductor layer 142. The third single-crystal semiconductor layer 143 extends in the Z-axis direction. The single-crystal semiconductor layer 14 may not include an interface between the third single-crystal semiconductor layer 143 and the second single-crystal semiconductor layer 142. For the other description of the third single-crystal semiconductor layer 143, the description of the single-crystal semiconductor layer of the first to seventh embodiments can be used as appropriate.

FIGS. 22 to 24 are schematic diagrams showing an example of the method for manufacturing the semiconductor storage device shown in FIG. 21, and show a part of the X-Z cross section of the semiconductor storage device 1.

In the example of the method for manufacturing the semiconductor storage device shown in FIG. 21, first as shown in FIG. 22, the stacked body 12, the memory film 13, the first single-crystal semiconductor layer 141, and the second single-crystal semiconductor layer 142 are formed above the single-crystal semiconductor substrate 11 using a method similar to that of the first embodiment.

Similar to the first embodiment, in a case of annealing the amorphous semiconductor layer 142a, when the opening 124 is too deep, a part of the amorphous semiconductor layer 142a may remain without being single-crystallized, and the second single-crystal semiconductor layer 142 may be thin as shown in FIG. 22.

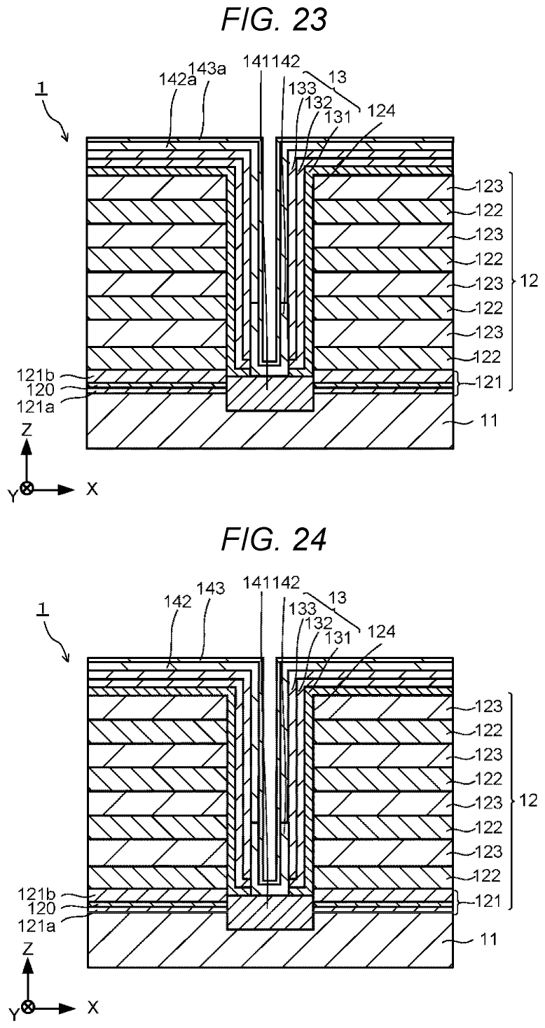

In response to this, as shown in FIG. 23, the amorphous semiconductor layer 143a is further formed above the amorphous semiconductor layer 142a and the second single-crystal semiconductor layer 142 and is annealed. Accordingly, as shown in FIG. 24, the amorphous semiconductor layer 142a and the amorphous semiconductor layer 143a are crystallized, and the second single-crystal semiconductor layer 142 and the third single-crystal semiconductor layer 143 having the crystal orientation same as the crystal orientation of the single-crystal semiconductor substrate 11 and the crystal orientation of the first single-crystal semiconductor layer 141 can be formed. For the other description of the amorphous semiconductor layer 143a, the description of the amorphous semiconductor layer 143a of the seventh embodiment can be used as appropriate. For annealing conditions, the conditions of the first embodiment can be used as appropriate.

By annealing the amorphous semiconductor layer 142a, an oxide film such as a silicon oxide film may be formed on a surface of the second single-crystal semiconductor layer 142. At this time, the oxide film such as a silicon oxide film formed on the surface of the second single-crystal semiconductor layer 142 may be removed by dry etching before the amorphous semiconductor layer 143a is formed.

Thereafter, by a surface treatment such as CMP, a part of the memory film 13, a part of the second single-crystal semiconductor layer 142, and a part of the third single-crystal semiconductor layer 143 are removed and the core insulating film 15 is formed. Through the above steps, the semiconductor storage device 1 shown in FIG. 21 can be manufactured.

In this way, in the present embodiment, the channel formation region is constituted using the single-crystal semiconductor layer 14 having the crystal orientation same as the crystal orientation of the single-crystal semiconductor substrate 11. Accordingly, the carrier mobility of the channel formation region can be increased. In addition, in the present embodiment, since the single-crystal semiconductor layer 14 can be formed without adding a metal catalyst to the amorphous semiconductor layer 142a and the amorphous semiconductor layer 143a, for example, the decrease in reliability of the tunnel insulating film 133 can be prevented.

When the opening 124 is too deep and the amorphous semiconductor layer 142a is single-crystallized, the single-crystal semiconductor layer 14 may be divided by migration. In order to deal with this, the single-crystal semiconductor layer 14 is formed in a plurality of steps, so that the single-crystal semiconductor layer 14 is prevented from being divided.

The present embodiment can be combined with other embodiments as appropriate. For example, similar to the second embodiment, the single-crystal semiconductor layer 14 may be constituted without forming the first single-crystal semiconductor layer 141.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device, comprising:
a single-crystal semiconductor substrate, the semiconductor substrate having a recessed surface;
an under layer provided over the semiconductor substrate;
a stacked body, provided over the under layer, that includes at least one conductive layer and at least one insulating layer alternately stacked on top of one another;
a single-crystal semiconductor layer extending in a first direction perpendicular to the semiconductor substrate, penetrating the stacked body, and including a first end in contact with the recessed surface of the semiconductor substrate; and
a memory film provided between the semiconductor layer and the at least one conductive layer, wherein
a crystal orientation of the semiconductor layer and a crystal orientation of the semiconductor substrate are the same.

2. The semiconductor storage device according to claim 1, wherein the semiconductor layer includes:
a first single-crystal semiconductor layer including the first end in contact with the recessed surface of the semiconductor substrate, and a second end located in the under layer; and
a second single-crystal semiconductor layer including a first end in contact with the second end of the first single-crystal semiconductor layer, the second single-crystal semiconductor layer and the conductive layer forming at least a portion of a memory cell.

3. The semiconductor storage device according to claim 2, wherein an impurity concentration of the first single-crystal semiconductor layer is higher than an impurity concentration of the second single-crystal semiconductor layer.

4. The semiconductor storage device according to claim 2, wherein an impurity concentration of a first portion of the second single-crystal semiconductor layer adjacent to an interface between the second single-crystal semiconductor layer and the first single-crystal semiconductor layer is higher than an impurity concentration of a second portion of the second single-crystal semiconductor layer adjacent to the memory cell.

5. The semiconductor storage device according to claim 3, wherein the impurity contains boron.

6. The semiconductor storage device according to claim 2, wherein the second single-crystal semiconductor layer extends in the first direction.

7. The semiconductor storage device according to claim 2, wherein the semiconductor layer further includes:
a third single-crystal semiconductor layer having an end in contact with the second single-crystal semiconductor layer.

8. The semiconductor storage device according to claim 1, further comprising: a select gate line provided between the under layer and the at least one conductive layer next to the semiconductor substrate.

9. A semiconductor storage device, comprising:
a single-crystal semiconductor substrate;
an interlayer insulating layer provided over the semiconductor substrate;
a wiring layer including a single-crystal layer provided over the interlayer insulating layer;
an under layer provided over the interlayer insulating layer;
a stacked body, provided over the under layer, that includes at least one conductive layer and at least one insulating layer alternately stacked on top of one another;
a single-crystal semiconductor layer extending in a first direction perpendicular to the semiconductor substrate, penetrating the stacked body, and including a first end in contact with the wiring layer; and
a memory film provided between the conductive layer and the semiconductor layer, wherein
a crystal orientation of the semiconductor layer and a crystal orientation of the single-crystal layer are the same.

10. The semiconductor storage device according to claim 9, further comprising: a catalyst layer, provided over the interlayer insulating layer, that contains a metal catalyst in contact with the wiring layer.

11. The semiconductor storage device according to claim 10, wherein a concentration of a metal catalyst in the semiconductor layer is lower than a concentration of a metal catalyst in the single-crystal layer.

12. The semiconductor storage device according to claim 10, wherein the single-crystal layer includes:
a first single-crystal layer spaced from the catalyst layer and in contact with the semiconductor layer; and
a second single-crystal layer spaced from the first single-crystal layer and in contact with the catalyst layer.

13. The semiconductor storage device according to claim 12, wherein
the semiconductor layer contains hydrogen, and
a hydrogen concentration of the semiconductor layer is higher than a hydrogen concentration of the semiconductor substrate.

14. The semiconductor storage device according to claim 9, wherein an impurity concentration of the wiring layer is higher than an impurity concentration of the semiconductor layer.

15. The semiconductor storage device according to claim 14, wherein the impurity contains boron.

16. The semiconductor storage device according to claim 9, further comprising: a select gate line provided between the under layer and the conductive layer closest to the interlayer insulating layer.

17. The semiconductor storage device according to claim 9, wherein the memory film includes a block insulating film, and the block insulating film is in contact with the wiring layer.

18. The semiconductor storage device according to claim 9, wherein the wiring layer intersects with the first direction and extends in a second direction parallel to the surface of the semiconductor substrate.

19. The semiconductor storage device according to claim 1, wherein
the semiconductor layer contains hydrogen, and
a hydrogen concentration of the single-crystal semiconductor layer is higher than a hydrogen concentration of the semiconductor substrate.
